(19) United States
(12) Patent Application Publication
(10) Pub. No.: US 2013/0285049 A1
(43) Pub. Date: Oct. 31, 2013

(54) STANDARD CELL AND SEMICONDUCTOR INTEGRATED CIRCUIT

(71) Applicant: SEMICONDUCTOR ENERGY LABORATORY CO., LTD., Atsugi-shi (JP)

(72) Inventors: Takuro Ohmaru, Isehara, Kanagawa (JP); Atsushi Miyaguchi, Atsugi, Kanagawa (JP)

(73) Assignee: Semiconductor Energy Laboratory Co., Ltd., Atsugi-shi (JP)

(21) Appl. No.: 13/868,270

(22) Filed: Apr. 23, 2013

(30) Foreign Application Priority Data
Apr. 27, 2012 (JP) 2012-102166

(51) Int. Cl. H01L 29/786

(52) U.S. Cl. CPC H01L 29/7869
USPC 257/43

(57) ABSTRACT

A standard cell and a semiconductor integrated circuit which enable a reduction in layout area are provided. A power source line for supplying a high power source potential and a power source line for supplying a low power source potential are arranged in the same wiring layer, and a power source line for supplying a back-gate electrode with a voltage for controlling a threshold voltage is provided to overlap with one of the two power source lines. Further, standard cells each requiring a different number of power source lines are arranged in the same cell row, and a different number of power source lines are connected to each cell row, whereby the number of unnecessary power source lines is reduced so that layout area is reduced.

### BACKGROUND OF THE INVENTION

1. Field of the Invention

The present invention relates to a standard cell and a semiconductor integrated circuit including the standard cell.

2. Description of the Related Art

Semiconductor integrated circuits (also referred to as semiconductor devices) such as application specific integrated circuits (ASICs) are broadly classified into semi-custom circuits and full-custom circuits. The semi-custom circuits are designed using a gate array, a standard cell methodology, and the like in order to shorten the design period. In the standard cell methodology, a predetermined function is realized by logic synthesis of standard cells prepared in advance in a standard cell library, followed by place and route of the standard cells.

Standard cells are function blocks combining basic gates used for logic synthesis and place and route, and are arranged between power source lines by place and route so as to have the same cell height. Proposed is a circuit configuration technology in which semiconductor layers with different materials are provided in the respective wiring layers to form function blocks (see Patent Document 1).

### REFERENCE

### Patent Document

[Patent Document 1] Japanese Published Patent Application No. 2012-69932

### SUMMARY OF THE INVENTION

In the case where semiconductor layers with different materials are provided in the respective wiring layers, another power source line is added in some cases. For example, in order to control the threshold voltage of a transistor, a back-gate electrode is sometimes provided and a power source line is additionally provided so that a voltage is applied to a back-channel side. Therefore, a standard cell in which semiconductor layers with different materials are provided in the respective wiring layers requires a power source line for applying a voltage to a back-channel side, in addition to a power source line for supplying a high power source potential (VDD) and a power source line for supplying a low power source potential (VSS or ground).

However, when another power source line is provided in addition to the power source line for supplying a high power source potential and the power source line for supplying a low power source potential, the three power source lines are provided, which leads to an increase in the layout area of the standard cell.

Furthermore, in a semiconductor integrated circuit, a standard cell requiring the three power source lines is sometimes arranged in the same cell row as a standard cell which requires not more than two power source lines. That is, standard cells requiring different numbers of power source lines are provided in the same cell row. In that case, the standard cell which requires not more than two power source lines has a problem in that the number of power source lines is merely increased and the layout area cannot be reduced.

Thus, an object of one embodiment of the present invention is to provide a standard cell which enables a reduction in layout area even when semiconductor layers with different materials are provided in the respective wiring layers.

Another object of one embodiment of the present invention is to provide a semiconductor integrated circuit including standard cells requiring different numbers of power source lines, in which a reduction in layout area can be achieved in a cell row including a standard cell requiring a smaller number of power source lines.

In order to solve the aforementioned problems, in one embodiment of the present invention, a power source line for supplying a high power source potential and a power source line for supplying a low power source potential are arranged in the same wiring layer, and a power source line for supplying a back-gate electrode with a voltage for controlling a threshold voltage is provided to overlap with one of the two power source lines. In another embodiment of the present invention, standard cells each requiring a different number of power source lines are arranged in the same cell row, and a different number of power source lines are connected to each cell row, whereby the number of unnecessary power source lines is reduced so that layout area is reduced.

One embodiment of the present invention is a standard cell including a first wiring layer provided with a first power source line, a second power source line, and a first transistor; a second wiring layer over the first wiring layer, which is provided with a third power source line; and a third wiring layer over the second wiring layer, which is provided with a second transistor. The third power source line applies a voltage to a back-channel side of the second transistor, and overlaps with the first power source line or the second power source line.

In the standard cell of one embodiment of the present invention, the third power source line preferably has a width smaller than that of the first power source line.

In the standard cell of one embodiment of the present invention, it is preferable that the first power source line supply a high power source potential and the second power source line supply a ground potential.

In the standard cell of one embodiment of the present invention, it is preferable that the first transistor include a silicon semiconductor layer and the second transistor include an oxide semiconductor layer.

One embodiment of the present invention is a semiconductor integrated circuit including a plurality of first standard cells provided with a first power source line, a second power source line, and a first transistor which are provided in a first wiring layer, a third power source line provided in a second wiring layer over the first wiring layer, and a second transistor provided in a third wiring layer over the second wiring layer; and a plurality of second standard cells provided with the first power source line, the second power source line, and the first transistor which are provided in the same layer as the first wiring layer, a first electrode portion provided in the same layer as the second wiring layer, and a second electrode portion provided in the same layer as the third wiring layer. The first standard cells are provided in a first cell row, and the second standard cells are provided in a second cell row.

One embodiment of the present invention is a semiconductor integrated circuit including a plurality of first standard cells provided with a first power source line, a second power source line, and a first transistor which are provided in a first wiring layer, a third power source line provided in a second wiring layer over the first wiring layer, and a second transistor provided in a third wiring layer over the second wiring layer; and a plurality of second standard cells provided with the first power source line, the second power source line, and the first transistor which are provided in the same layer as the first wiring layer, a first electrode portion provided in the same layer as the second wiring layer, and a second electrode portion provided in the same layer as the third wiring layer. The first standard cells are provided in a first cell row, and the second standard cells are provided in a second cell row. The third power source line applies a voltage to a back-channel side of the second transistor, and overlaps with the first power source line.

In the semiconductor integrated circuit of one embodiment of the present invention, the third power source line preferably has a width smaller than that of the first power source line.

In the semiconductor integrated circuit of one embodiment of the present invention, it is preferable that the first power source line supply a high power source potential and the second power source line supply a ground potential.

In the semiconductor integrated circuit of one embodiment of the present invention, it is preferable that the first transistor include a silicon semiconductor layer and the second transistor include an oxide semiconductor layer.

In the semiconductor integrated circuit of one embodiment of the present invention, the second standard cells are preferably provided in the first cell row.

The standard cell of one embodiment of the present invention achieves a reduction in the layout area and a reduction in the influence of noise of power source lines supplying power source voltages. According to one embodiment of the present invention, it is also possible to provide a semiconductor integrated circuit whose layout area is reduced and whose number of unnecessary power source lines is prevented from increasing.

### BRIEF DESCRIPTION OF THE DRAWINGS

In the accompanying drawings:

FIGS. 1A to 1C are schematic views illustrating a structure of a standard cell and a semiconductor integrated circuit;

FIGS. 2A-1, 2A-2, 2B-1, and 2B-2 are schematic views illustrating a structure of a standard cell;

FIG. 3 is a schematic view illustrating an arrangement of standard cells in a semiconductor integrated circuit; and

FIGS. 4A and 4B are schematic views each illustrating an arrangement of standard cells in a semiconductor integrated circuit.

### DETAILED DESCRIPTION OF THE INVENTION

Hereinafter, embodiments of the present invention will be described with reference to the drawings. However, the present invention can be implemented in many different modes, and it is easily understood by those skilled in the art that modes and details of the present invention can be modified in various ways without departing from the spirit and the scope of the present invention. Therefore, the present invention is not construed as being limited to the description of the embodiments. Note that in the structures of the present invention described below, reference numerals denoting the same portions are used in common in different drawings.

Note that the size, layer thickness, and signal waveform of components illustrated in the drawings and the like in the embodiments are exaggerated for simplicity in some cases. Therefore, the embodiments of the present invention are not limited to such scales.

Functions of a “source” and a “drain” of a transistor are sometimes replaced with each other when a transistor of opposite polarity is used or when the direction of current flowing is changed in circuit operation, for example. Therefore, the terms “source” and “drain” can be used to denote the drain and the source, respectively, in this specification.

Also in this specification and the like, the term such as “electrode” or “wiring” does not limit a function of a component. For example, an “electrode” is sometimes used as part of a “wiring”, and vice versa. Further, the term “electrode” or “wiring” can include the case where a plurality of “electrodes” or “wirings” are formed in an integrated manner.

In this specification, a term “parallel” indicates that the angle formed between two straight lines is greater than or equal to −10° and less than or equal to 10°, and accordingly also includes the case where the angle is greater than or equal to −5° and less than or equal to 5°. In addition, a term “perpendicular” indicates that the angle formed between two straight lines is greater than or equal to 80° and less than or equal to 100°, and accordingly includes the case where the angle is greater than or equal to 85° and less than or equal to 95°.

In this specification, the trigonal and rhombohedral crystal systems are included in the hexagonal crystal system.

### Embodiment 1

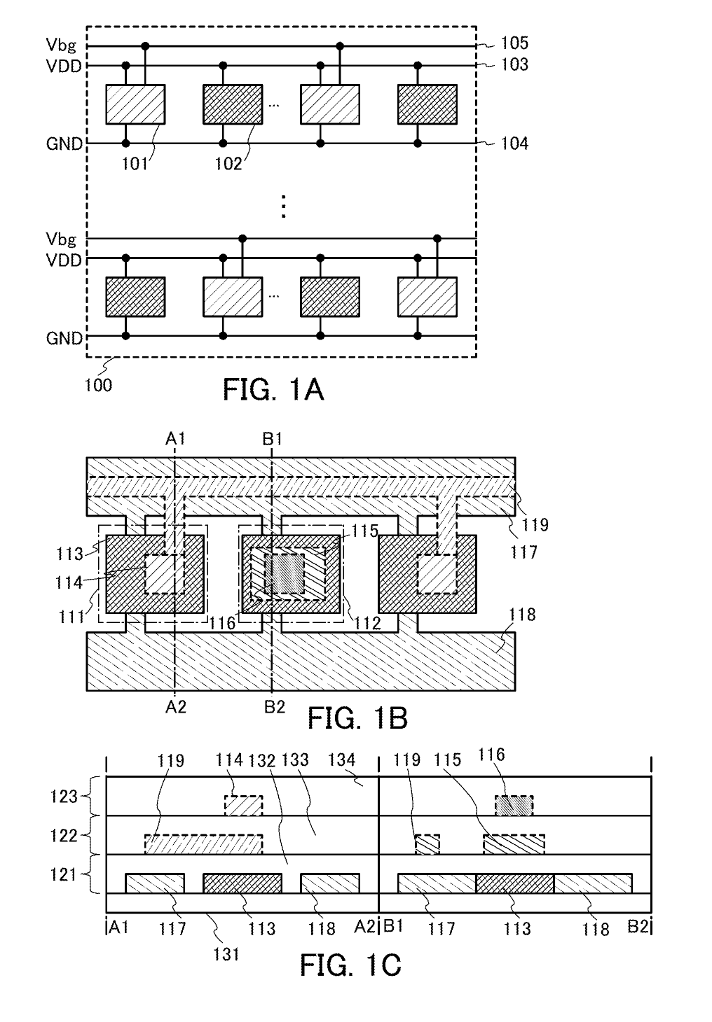

A semiconductor integrated circuit 100 includes, as illustrated in FIG. 1A, a first standard cell 101 provided with a transistor using silicon for a semiconductor layer and a transistor using an oxide semiconductor for a semiconductor layer; and a second standard cell 102 provided with a transistor using silicon for a semiconductor layer.

Note that in this specification, a semiconductor integrated circuit and a standard cell each are a device including a semiconductor element. Therefore, the semiconductor integrated circuit and the standard cell can be referred to as semiconductor devices. Note that a semiconductor device refers to a circuit or a device including a semiconductor element.

In the semiconductor integrated circuit 100, a first power source line 103, a second power source line 104, and a third power source line 105 which supply a high power source potential VDD, a low power source potential GND, and a back-gate voltage Vbg, respectively, are provided in each cell row. In each cell row, the first standard cell 101 and the second standard cell 102 can be provided between the first power source line 103 and the third power source line 105, and the second power source line 104.

In the first standard cell 101, a first wiring layer, a second wiring layer, and a third wiring layer are stacked and electrically connect to each other.

The first wiring layer included in the first standard cell 101 includes the first power source line 103, the second power source line 104, and a first transistor. In other words, the first wiring layer includes a gate wiring and a source wiring for connecting the first power source line 103, the second power source line 104, and the first transistor. Note that the first transistor preferably includes a silicon semiconductor layer. A circuit configuration with miniaturized transistors is realized by placing the transistor including a silicon semiconductor layer in the first wiring layer in the lower layer.

The second wiring layer included in the first standard cell 101 is provided over the first wiring layer and includes the third power source line 105. The third power source line 105 can be provided to overlap with the first power source line 103 or the second power source line 104 in the first wiring layer. Note that the second wiring layer is used as a wiring layer for electrically connecting the first wiring layer to the third wiring layer. The second wiring layer is also used as a layer in which a back-gate electrode of a second transistor in the third wiring layer is provided. Furthermore, the second wiring layer is used as a layer in which a wiring for applying a voltage to the back-gate side of the second transistor is provided.

Note that a bias applied to the back-channel side of the second transistor is also referred to as a back-gate voltage. The back channel refers to a channel formed in a side of a semiconductor layer which is not in contact with a gate insulating film. The back-channel side refers to the side of the semiconductor layer which is not in contact with the gate insulating film. The threshold voltage of the second transistor can be controlled with the bias applied to the back-channel side (the back-gate voltage).

The third wiring layer included in the first standard cell 101 is provided over the second wiring layer and includes a second transistor. In other words, the third wiring layer includes a gate wiring and a source wiring for connecting the second transistors. Note that the second transistor preferably includes an oxide semiconductor layer. The use of an oxide semiconductor layer for the second transistor allows a significant reduction in the current flowing between a source and a drain when the transistor is off (hereinafter referred to as an off-state current). When the second transistor with an extremely low off-state current is combined with the first transistor using a silicon semiconductor layer, it is possible to provide a function block used as a memory device in which data charge can be held even when power supply is stopped.

Note that when the size of the second transistor is larger than that of the first transistor, a short-channel effect or the like do not occur in the second transistor, so that the transistor with stable characteristics can be obtained. Further, a reduction in the number of the second transistors in the third wiring layer increases the degree of freedom in placing and routing the third wiring layer.

In the second standard cell 102, a first wiring layer, a second wiring layer, and a third wiring layer are stacked and electrically connect to each other.

The first wiring layer included in the second standard cell 102 includes the first power source line 103, the second power source line 104, and a first transistor. In other words, the first wiring layer includes a gate wiring and a source wiring for connecting the first power source line 103, the second power source line 104, and the first transistor. Note that the first transistor in the second standard cell 102 is similar to the transistor using a silicon semiconductor layer in the aforementioned first standard cell 101.

The second wiring layer included in the second standard cell 102 is provided over the first wiring layer and includes a wiring layer provided in the same layer as the third power source line 105. The wiring layer in the second standard cell 102, which is provided in the same layer as the third power source line 105, is not a power source line supplied with a predetermined voltage, and can be used as a wiring for electrically connecting the first wiring layer to the third wiring layer or connecting the first transistors included in the first wiring layer. In addition, the wiring layer in the second standard cell 102, which is provided in the same layer as the third power source line 105, can be provided without being connected to the third power source line 105.

The third wiring layer included in the second standard cell 102 is provided over the second wiring layer and includes a wiring layer provided in the same layer as the gate wiring and the source wiring included in the second transistor in the first standard cell 101. The wiring layer included in the second standard cell 102 is not a power source line supplied with a predetermined voltage, and can be used as a wiring for electrically connecting the second wiring layer to a layer over the third wiring layer. Although not illustrated, a wiring for connecting the standard cells is provided over the third wiring layer.

The aforementioned first wiring layer, second wiring layer, and third wiring layer included in each of the first standard cell 101 and the second standard cell 102 are arranged in the manner illustrated in FIGS. 1B and 1C. FIG. 1B is a schematic top view of the first standard cell 101 and the second standard cell 102, and FIG. 1C is a schematic cross-sectional view along dashed lines A1-A2 and B1-B2 of FIG. 1B.

In FIG. 1B, a first standard cell 111 and a second standard cell 112 are provided between a first power source line 117 and a third power source line 119, and a second power source line 118.

The first standard cell 111 includes a first transistor portion 113 electrically connected to the first power source line 117 and the second power source line 118, and a second transistor portion 114 which overlaps with a back-gate electrode extending from the third power source line 119. The back-gate electrode extending from the third power source line 119 is in a second wiring layer.

Note that the first transistor portion 113 includes first transistors. The number of transistors in the first transistor portion 113 differs depending on the function block which is a standard cell. The second transistor portion 114 includes second transistors. The number of transistors in the second transistor portion 114 differs depending on the function block which is a standard cell.

Note that the third power source line 119 overlapping with the first power source line 117 preferably has a width smaller than that of the first power source line 117 as illustrated in FIG. 1B. Unlike the first power source line 117, the third power source line 119 applies voltage only to the second transistor and hardly supplies any current to the other elements such as transistors. Therefore, the width of the third power source line 119 can be made smaller than that of the first power source line 117, leading to a reduction in load in charging and discharging the third power source line 119.

The second standard cell 112 as well as the first standard cell 111 includes the first transistor portion 113 electrically connected to the first power source line 117 and the second power source line 118. The second standard cell 112 also includes a first electrode portion 115 and a second electrode portion 116 which overlap with the first transistor portion 113. Note that the first electrode portion 115 is provided in the same layer as the third power source line 119. The second electrode portion 116 is provided in the same layer as the second transistor portion 114 included in the first standard cell 111.

Note that the first electrode portion 115 is an electrode serving as a wiring, which is provided in the same layer as the third power source line 119. The second electrode portion 116 is an electrode serving as a wiring, which is provided in the same layer as a gate wiring and a source wiring in the second transistor portion 114.

FIG. 1C is a schematic view of a first wiring layer 121, a second wiring layer 122, and a third wiring layer 123 along dashed lines A1-A2 and B1-B2 of FIG. 1B.

In the cross-section of the first wiring layer 121 along dashed line A1-A2, the first power source line 117, the second power source line 118, and the first transistor portion 113 are provided over a substrate 131. Although the first power source line 117 and the second power source line 118 are not in direct contact with each other in FIG. 1C, actually, they are in contact with each other so as to supply a power source voltage to the first transistor portion 113. The first power source line 117, the second power source line 118, and the first transistor portion 113 are covered with an interlayer insulating layer 132. Note that the first power source line 117, the second power source line 118, and the first transistor portion 113 are electrically connected to the second wiring layer 122 or the third wiring layer 123 through openings (not illustrated) provided in the interlayer insulating layer 132.

In the cross-section of the second wiring layer 122 along dashed line A1-A2, the third power source line 119 serving as a back-gate electrode of the second transistor is provided over the first power source line 117 and the first transistor portion 113 in the first wiring layer 121. The third power source line 119 is covered with an interlayer insulating layer 133, and electrically connected to the third wiring layer 123 through an opening (not illustrated) provided in the interlayer insulating layer 133.

In the cross-section of the third wiring layer 123 along dashed line A1-A2, the second transistor portion 114 is provided over the third power source line 119. The second transistor portion 114 is covered with an interlayer insulating layer 134, and electrically connected to a wiring over the third wiring layer 123 through an opening provided in the interlayer insulating layer 134. Although not illustrated, a wiring for connecting the standard cells is provided over the third wiring layer 123. The wiring for connecting the standard cells may have a multi-layer structure.

In the cross-section of the first wiring layer 121 along dashed line B1-B2, the first transistor portion 113 electrically connected to the first power source line 117 and the second power source line 118 is provided over the substrate 131. Note that the first power source line 117, the second power source line 118, and the first transistor portion 113 are electrically connected to the second wiring layer 122 or the third wiring layer 123 through openings (not illustrated) provided in the interlayer insulating layer 132.

In the cross-section of the second wiring layer 122 along dashed line B1-B2, the first electrode portion 115 is provided over the first transistor portion 113 in the first wiring layer 121. The first electrode portion 115 is covered with the interlayer insulating layer 133, and electrically connected to the third wiring layer 123 through an opening (not illustrated) provided in the interlayer insulating layer 133.

In the cross-section of the third wiring layer 123 along dashed line B1-B2, the second electrode portion 116 is provided over the first electrode portion 115. The second electrode portion 116 is covered with the interlayer insulating layer 134 and electrically connected to an electrode over the third wiring layer 123 through an opening (not illustrated) provided in the interlayer insulating layer 134. Although not illustrated, a wiring for connecting the standard cells is provided over the third wiring layer 123. The wiring for connecting the standard cells may have a multi-layer structure.

As described with reference to FIGS. 1B and 1C, the standard cells shown in this embodiment include not only the first power source line for supplying a high power source potential and the second power source line for supplying a low power source potential, but also the third power source line for applying a voltage to the back-gate electrode of the second transistor. Thus, the layout area of the standard cells increases because of the three power source lines if nothing is done. In this embodiment, the third power source line for applying a voltage to the back-channel side of the second transistor overlaps with the first power source line, which results in a reduction in the layout area of the standard cells.

Although the third power source line 119 overlaps with the first power source line 117 in FIG. 1B, the third power source line 119 may overlap with the second power source line 118.

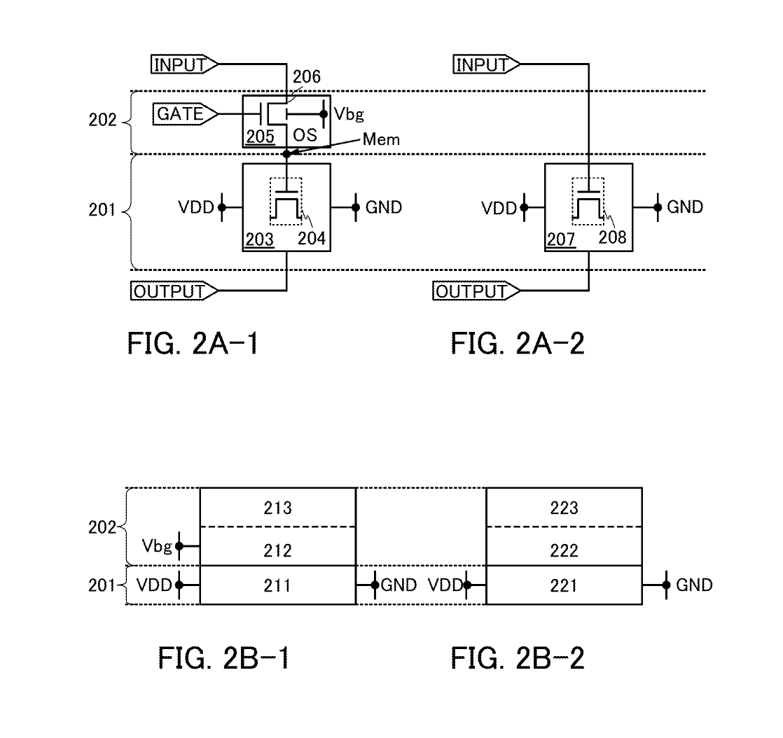

FIGS. 2A-1, 2A-2, 2B-1, and 2B-2 are simple circuit diagrams and corresponding diagrams showing the first standard cell and the second standard cell illustrated in FIGS. 1A to 1C, which include the first wiring layer, the second wiring layer, and the third wiring layer. An effect of the structure of this embodiment will be described in detail.

FIG. 2A-1 illustrates a circuit structure of the first standard cell including a first transistor and a second transistor. FIG. 2A-2 illustrates a circuit structure of the second standard cell including a first transistor.

In FIG. 2A-1, a first element layer 201 includes a first transistor portion 203 provided with a first power source line (VDD), a second power source line (GND), and a first transistor 204, and a second element layer 202 includes a second transistor portion 205 provided with a second transistor 206 including a back-gate electrode connected to a third power source line (Vbg).

In FIG. 2A-2, the first element layer 201 includes a first transistor portion 207 provided with the first power source line (VDD), the second power source line (GND), and a first transistor 208. Note that the second standard cell in FIG. 2A-2 does not include a transistor in the same layer as the second transistor 206 in FIG. 2A-1, and thus only a wiring is illustrated.

Next, operation of the first standard cell illustrated in FIG. 2A-1 will be described. The first standard cell in FIG. 2A-1 includes, for example, a circuit structure functioning as a memory circuit.

In the circuit structure of FIG. 2A-1, an input signal INPUT is input to a terminal serving as a source or a drain of the second transistor 206. A control signal GATE input to a gate of the second transistor 206 controls the supply of the input signal INPUT to a node Mem. A back-gate voltage Vbg applied to the back-gate electrode of the second transistor 206 is applied to a back-channel side of the second transistor 206, thereby controlling a threshold voltage so that the second transistor 206 is normally on.

The second transistor 206 has a leakage current in an off state (hereinafter referred to as an off-state current) much lower than that of a transistor including a silicon semiconductor layer. The second transistor 206 includes an oxide semiconductor layer. Note that in the drawing, the second transistor 206 is denoted by OS in order to show that an oxide semiconductor is used for the semiconductor layer of the second transistor 206.

Here, the oxide semiconductor used for the semiconductor layer of the second transistor 206 will be described in detail.

At least indium (In) or zinc (Zn) is preferably contained as the oxide semiconductor used for the semiconductor layer of the transistor. In particular, In and Zn are preferably contained. A stabilizer for strongly bonding oxygen is preferably contained in addition to In and Zn. As the stabilizer, at least one of gallium (Ga), tin (Sn), zirconium (Zr), hafnium (Hf), and aluminum (Al) may be contained.

As another stabilizer, one or plural kinds of lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu) may be contained.

As the oxide semiconductor, the following can be used, for example: a four-component metal oxide such as an In—Sn—Ga—Zn-based oxide; a three-component metal oxide such as an In—Ga—Zn-based oxide, an In—Sn—Zn-based oxide, an In—Zr—Zn-based oxide, an In—Al—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an

In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide; a two-component metal oxide such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide; or a one-component metal oxide such as an In-based oxide, a Sn-based oxide, or a Zn-based oxide.

Note that here, for example, an In—Ga—Zn-based oxide refers to an oxide mainly containing In, Ga, and Zn, and there is no limitation on the ratio of In to Ga and Zn.

Alternatively, a material represented by InMO₃(ZnO)ₘ (m>0) may be used as the oxide semiconductor. Note that M represents one or more metal elements selected from Ga, Fe, Mn, and Co. Still alternatively, a material represented by In₂SnO₅(ZnO)ₙ (n>0) may be used as the oxide semiconductor.

For example, an In—Ga—Zn-based oxide with an atomic ratio of In:Ga:Zn=3:1:2, In:Ga:Zn=1:1:1, or In:Ga:Zn=2:2:1, or an oxide whose atomic ratio is in the neighborhood of the above atomic ratios can be used. Alternatively, an In—Sn—Zn-based oxide with an atomic ratio of In:Sn:Zn=1:1:1, In:Sn:Zn=2:1:3, or In:Sn:Zn=2:1:5, or an oxide whose atomic ratio is in the neighborhood of the above atomic ratios may be used.

Note that for example, the expression “the composition of an oxide including In, Ga, and Zn at the atomic ratio, In:Ga:Zn=a:b:c (a+b+c=1), is in the neighborhood of the composition of an oxide including In, Ga, and Zn at the atomic ratio, In:Ga:Zn=A:B:C (A+B+C=1)” means that a, b, and c satisfy Formula (1).

(a−A)²+(b−B)²+(c−C)²≦r² (1)

For example, r may be 0.05. The same applies to other oxides.

However, the composition of the oxide semiconductor is not limited to those described above, and an oxide semiconductor having an appropriate composition may be used depending on necessary semiconductor characteristics (e.g., field-effect mobility or threshold voltage). In order to obtain the required semiconductor characteristics, it is preferable that the carrier concentration, the impurity concentration, the defect density, the atomic ratio between a metal element and oxygen, the interatomic distance, the density, and the like be set to appropriate values.

The off-state current of a transistor can be sufficiently reduced by using a highly purified oxide semiconductor for a semiconductor layer (here, the off-state current means a drain current when a potential difference between a source and a gate is equal to or lower than the threshold voltage in the off state, for example). A highly purified oxide semiconductor can be obtained, for example, in such a manner that a film is deposited while heating is performed so as to prevent hydrogen and a hydroxyl group from being contained in the oxide semiconductor, or heat treatment is performed after film deposition so as to remove hydrogen and a hydroxyl group from the film. In the case where a highly purified In—Ga—Zn-based-oxide semiconductor is used for a channel region of a transistor having a channel length of 10 μm, a semiconductor film thickness of 30 nm, and a drain voltage of about 1 V to 10 V, the off-state current of the transistor can be reduced to 1×10⁻¹³ A or less. In addition, the off-state current per channel width (the value obtained by dividing the off-state current by the channel width of the transistor) can be made about 1×10⁻²³ A/μm (10 yA/μm) to 1×10⁻²² A/μm (100 yA/μm).

The deposited oxide semiconductor film is classified roughly into a single-crystal oxide semiconductor film and a non-single-crystal oxide semiconductor film. The non-single-crystal oxide semiconductor film includes any of an amorphous oxide semiconductor film, a microcrystalline oxide semiconductor film, a polycrystalline oxide semiconductor film, a c-axis aligned crystalline oxide semiconductor (CAAC-OS) film, and the like.

The amorphous oxide semiconductor film has disordered atomic arrangement and no crystalline component. A typical example thereof is an oxide semiconductor film in which no crystal part exists even in a microscopic region, and the whole of the film is amorphous.

The microcrystalline oxide semiconductor film includes a microcrystal (also referred to as nanocrystal) with a size greater than or equal to 1 nm and less than 10 nm, for example. Thus, the microcrystalline oxide semiconductor film has a higher degree of atomic order than the amorphous oxide semiconductor film. Hence, the density of defect states of the microcrystalline oxide semiconductor film is lower than that of the amorphous oxide semiconductor film.

The CAAC-OS film is one of oxide semiconductor films including a plurality of crystal parts, and most of the crystal parts each fit inside a cube whose one side is less than 100 nm. Thus, there is a case where a crystal part included in the CAAC-OS film fits inside a cube whose one side is less than 10 nm, less than 5 nm, or less than 3 nm. The density of defect states of the CAAC-OS film is lower than that of the microcrystalline oxide semiconductor film. The CAAC-OS film is described in detail below.

In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology reflected by a surface over which the CAAC-OS film is formed (hereinafter, a surface over which the CAAC-OS film is formed is referred to as a formation surface) or a top surface of the CAAC-OS film, and is arranged in parallel to the formation surface or the top surface of the CAAC-OS film.

On the other hand, according to the TEM image of the CAAC-OS film observed in a direction substantially perpendicular to the sample surface (plan TEM image), metal atoms are arranged in a triangular or hexagonal configuration in the crystal parts. However, there is no regularity of arrangement of metal atoms between different crystal parts.

From the results of the cross-sectional TEM image and the plan TEM image, alignment is found in the crystal parts in the CAAC-OS film.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor film of InGaZnO₄, six peaks appear. The six peaks are derived from crystal planes equivalent to the (110) plane. On the other hand, in the case of a CAAC-OS film, a peak is not clearly observed even when φ scan is performed with 2θ fixed at around 56°.

According to the above results, in the CAAC-OS film having c-axis alignment, while the directions of a-axes and b-axes are different between crystal parts, the c-axes are aligned in a direction parallel to a normal vector of a formation surface or a normal vector of a top surface. Thus, each metal atom layer arranged in a layered manner observed in the cross-sectional TEM image corresponds to a plane parallel to the a-b plane of the crystal.

Note that the crystal part is formed concurrently with deposition of the CAAC-OS film or is formed through crystallization treatment such as heat treatment. As described above, the c-axis of the crystal is aligned in a direction parallel to a normal vector of a formation surface or a normal vector of a top surface. Thus, for example, in the case where a shape of the CAAC-OS film is changed by etching or the like, the c-axis might not be necessarily parallel to a normal vector of a formation surface or a normal vector of a top surface of the CAAC-OS film.

Further, the degree of crystallinity in the CAAC-OS film is not necessarily uniform. For example, in the case where crystal growth leading to the CAAC-OS film occurs from the vicinity of the top surface of the film, the degree of the crystallinity in the vicinity of the top surface is higher than that in the vicinity of the formation surface in some cases. Further, when an impurity is added to the CAAC-OS film, the crystallinity in a region to which the impurity is added is changed, and the degree of crystallinity in the CAAC-OS film varies depending on regions.

Note that when the CAAC-OS film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS film. It is preferable that in the CAAC-OS film, a peak of 2θ appear at around 31° and a peak of 2θ do not appear at around 36°.

In a transistor using the CAAC-OS film, change in electric characteristics due to irradiation with visible light or ultraviolet light is small. Thus, the transistor has high reliability.

Note that an oxide semiconductor film may be a stacked film including two or more films of an amorphous oxide semiconductor film, a microcrystalline oxide semiconductor film, and a CAAC-OS film, for example.

That is the description of the oxide semiconductor used for the semiconductor layer of the second transistor 206.

Charge of the input signal INPUT illustrated in FIG. 2A-1 can be held in the node Mem between the other terminal of the second transistor 206 and a gate of the first transistor 204 when the second transistor 206 with low off-state current is turned off. An output signal OUTPUT corresponding to the input signal INPUT can be output from the first transistor portion 203 including the first transistor 204. The input signal INPUT can be held as the charge held in the node Mem. Since the charge held in the node Mem can be kept even when power supply is stopped, the first standard cell can be used as a function block of a non-volatile memory circuit.

The second standard cell illustrated in FIG. 2A-2 includes the first transistor 208 and outputs the output signal OUTPUT corresponding to the input signal INPUT with use of a power source voltage supplied from the first power source line (VDD) and the second power source line (GND). Thus, various function blocks can be obtained with a circuit configuration including the first transistor 208.

FIGS. 2B-1 and 2B-2 are schematic views illustrating the relationship between the first element layer 201 and the second element layer 202 illustrated in FIGS. 2A-1 and 2A-2, and the first wiring layer to the third wiring layer illustrated in FIGS. 1A to 1C.

FIG. 2B-1 is a schematic view illustrating the relationship between the first element layer 201 and the second element layer 202 in the first standard cell, and a first wiring layer 211, a second wiring layer 212, and a third wiring layer 213. FIG. 2B-2 is a schematic view illustrating the relationship between the first element layer 201 and the second element layer 202 in the second standard cell, and a first wiring layer 221, a second wiring layer 222, and a third wiring layer 223.

As illustrated in FIGS. 2B-1 and 2B-2, the first power source line (VDD) and the second power source line (GND) are provided in the same layer as the first wiring layer 211 and the first wiring layer 221, and the third power source line (Vbg) is provided in the second wiring layer 212. In the first standard cell, the third power source line (Vbg) of the second wiring layer 212 overlaps with the first power source line (VDD) of the first wiring layer 211. In the second standard cell, the second wiring layer 222 includes a wiring layer provided in the same layer as the third power source line (Vbg). Accordingly, the height of a cell column between the first power source line (VDD) and the second power source line (GND) in the first standard cell can be made equal to that in the second standard cell. In the case where the first standard cell and the second standard cell are arranged in the same cell row, place and route can be performed with the same cell row height. Further, the layout area of the semiconductor integrated circuit can be reduced because the third power source line (Vbg) overlaps with the first power source line (VDD).

In the structure of this embodiment, the third power source line applies only a back-gate voltage Vbg to the second transistor and hardly supplies any current. Therefore, the voltage of the third power source line hardly varies due to a current flowing therethrough. When the third power source line with an extremely small variation in voltage is provided so as to overlap with the first power source line or the second power source line, the influence of noise of the power source lines can be reduced as compared with the case where general power source lines overlap with each other.

As described above, in the standard cell shown in this embodiment, even when wiring layers including different transistors overlap with each other, a power source line for supplying a high power source potential does not overlap with a power source line for supplying a low power source potential, resulting in a reduction in the layout area.

### Embodiment 2

In this embodiment, the first standard cell and the second standard cell shown in Embodiment 1 are placed and routed in a semiconductor integrated circuit, and such a structure will be described with reference to drawings.

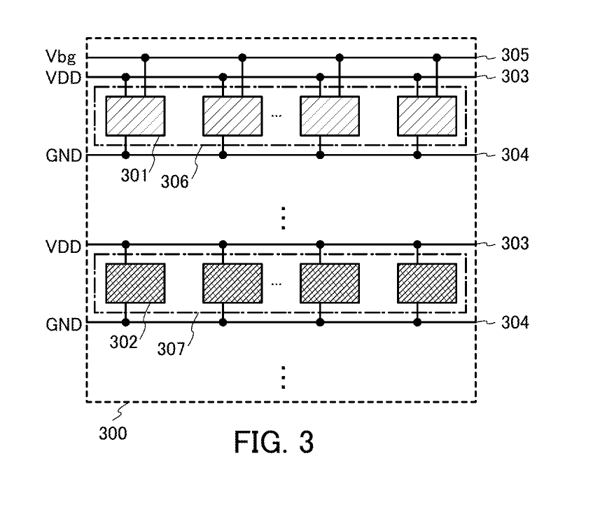

FIG. 3 is a schematic view of a semiconductor integrated circuit 300 including, as in FIG. 1A, a first standard cell 301 provided with a transistor including a silicon semiconductor layer and a transistor including an oxide semiconductor layer; and a second standard cell 302 provided with a transistor including a silicon semiconductor layer.

In the semiconductor integrated circuit 300 illustrated in FIG. 3, a first power source line 303, a second power source line 304, and a third power source line 305 which supply a high power source potential VDD, a low power source potential GND, and a back-gate voltage Vbg, respectively, are provided in a cell row 306 including the first standard cell 301. Further, the first power source line 303 and the second power source line 304 which supply the high power source potential VDD and the low power source potential GND, respectively, are provided in a cell row 307 including the second standard cell 302.

The arrangement of the first standard cell 301 and the second standard cell 302 in the semiconductor integrated circuit 300 illustrated in FIG. 3 is different from that illustrated in FIG. 1A in that standard cells requiring the same number of power source lines are provided in the same cell row. Such an arrangement that each cell row is provided with standard cells requiring the same number of power source lines leads to a reduction in the number of power source lines necessary in the semiconductor integrated circuit 300. As a result, the layout area of the semiconductor integrated circuit can be reduced.

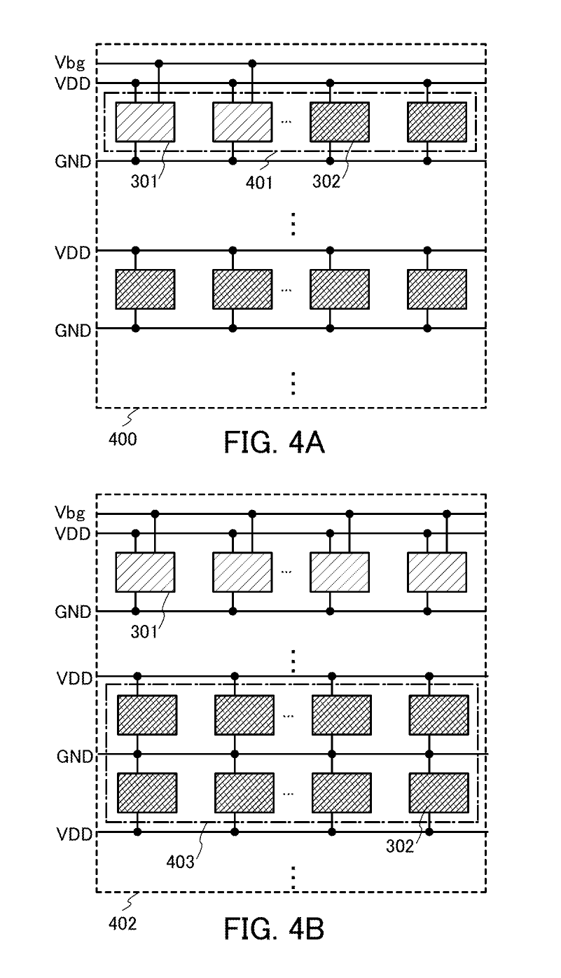

Note that in this embodiment, the following arrangement may be employed as in a semiconductor integrated circuit 400 illustrated in FIG. 4A: the first standard cell 301 and the second standard cell 302 are provided in a cell row 401 in which the first standard cell 301 is connected to a larger number of power source lines than the second standard cell 302. An effect similar to that in FIG. 3 can be obtained with such an arrangement because the number of power source lines does not increase.

Also in this embodiment, still another arrangement may be employed as in a semiconductor integrated circuit 402 illustrated in FIG. 4B: in a cell row 403 including the second standard cell 302 to which a power source voltage is supplied from a first power source line and a second power source line, the first power source lines are provided with the second power source line interposed therebetween, and the second standard cell 302 is provided between each of the first power source lines and the second power source line. Such an arrangement is more effective in reducing the layout area because the number of power source lines is reduced as compared with FIG. 3 and FIG. 4A.

By combining the aforementioned structures of this embodiment with the structure of Embodiment 1, the layout area can be further reduced.

This embodiment can be implemented in appropriate combination with the above embodiment.

This application is based on Japanese Patent Application serial No. 2012-102166 filed with Japan Patent Office on Apr. 27, 2012, the entire contents of which are hereby incorporated by reference.

What is claimed is:

1. A standard cell comprising:
a first wiring layer comprising a first power source line, a second power source line, and a first transistor;
a second wiring layer over the first wiring layer, the second wiring layer comprising a third power source line overlapping with the first power source line or the second power source line; and
a third wiring layer over the second wiring layer, the third wiring layer comprising a second transistor,
wherein the third power source line is configured to apply a voltage to a back-channel side of the second transistor.

2. The standard cell according to claim 1, wherein a width of the third power source line is smaller than a width of the first power source line.

3. The standard cell according to claim 1, wherein the first power source line is configured to supply a high power source potential and the second power source line is configured to supply a ground potential.

4. The standard cell according to claim 1, wherein a gate electrode of the first transistor is electrically connected to a source electrode or a drain electrode of the second transistor.

5. The standard cell according to claim 1, wherein a back gate electrode of the second transistor is provided in the second wiring layer.

6. The standard cell according to claim 1, wherein the first transistor comprises a silicon semiconductor layer and the second transistor comprises an oxide semiconductor layer.

7. The standard cell according to claim 6, wherein the oxide semiconductor layer comprises indium, gallium, and zinc.

8. The standard cell according to claim 6, wherein the oxide semiconductor layer is a c-axis aligned crystalline oxide semiconductor layer.

9. A semiconductor integrated circuit comprising:
first standard cells each comprising:
a first power source line, a second power source line, and a first transistor which are provided in a first wiring layer;
a third power source line provided in a second wiring layer over the first wiring layer, the third power source line overlapping with the first power source line or the second power source line; and
a second transistor provided in a third wiring layer over the second wiring layer; and
second standard cells each comprising:
the first power source line, the second power source line, and a third transistor which are provided in a same layer as the first wiring layer;
a first electrode portion provided in a same layer as the second wiring layer; and
a second electrode portion provided in a same layer as the third wiring layer,
wherein the third power source line is configured to apply a voltage to a back-channel side of the second transistor.

10. The semiconductor integrated circuit according to claim 9, wherein a width of the third power source line is smaller than a width of the first power source line.

11. The semiconductor integrated circuit according to claim 9, wherein the first power source line is configured to supply a high power source potential and the second power source line is configured to supply a ground potential.

12. The semiconductor integrated circuit according to claim 9, wherein a gate electrode of the first transistor is electrically connected to a source electrode or a drain electrode of the second transistor.

13. The semiconductor integrated circuit according to claim 9, wherein a back gate electrode of the second transistor is provided in the second wiring layer.

14. The semiconductor integrated circuit according to claim 9, wherein the first transistor and the third transistor each comprise a silicon semiconductor layer and the second transistor comprises an oxide semiconductor layer.

15. The semiconductor integrated circuit according to claim 14, wherein the oxide semiconductor layer comprises indium, gallium, and zinc.

16. The semiconductor integrated circuit according to claim 14, wherein the oxide semiconductor layer is a c-axis aligned crystalline oxide semiconductor layer.

17. The semiconductor integrated circuit according to claim 9, wherein the first standard cells and the second standard cells are provided in a same cell row.

18. The semiconductor integrated circuit according to claim 9,
wherein the first standard cells are provided in a first cell row, and
wherein the second standard cells are provided in a second cell row.

19. The semiconductor integrated circuit according to claim 18, wherein at least one of the second standard cells is provided in the first cell row.
